(19) United States
(12) Patent Application Publication
(10) Pub. No.: US 2025/0330152 A1
(43) Pub. Date: Oct. 23, 2025

(54) DUAL BAND RECONFIGURABLE BALUN CIRCUIT

(71) Applicant: Qorvo US, Inc., Greensboro, NC (US)

(72) Inventors: Ali Tombak, Cary, NC (US); Mehdi Naseri Ali Abadi, Mountain View, CA (US); Marcus Granger-Jones, Scotts Valley, CA (US)

(21) Appl. No.: 19/067,218

(22) Filed: Feb. 28, 2025

Related U.S. Application Data
(60) Provisional application No. 63/635,171, filed on Apr. 17, 2024.

(51) Int. Cl. H03H 11/32; H04B 1/00

(52) U.S. Cl. CPC H03H 11/32; H04B 1/006

(57) ABSTRACT

The present disclosure relates to a dual-band reconfigurable balun circuit, which includes a transformer structure having a primary winding and a secondary winding with two winding outputs, a first shunt switch coupled between one of the two winding outputs and ground, and a second shunt switch coupled between the other winding output and ground. Herein, the primary winding receives differential signals from an amplifier, and the secondary winding provides an unbalanced single signal at either of the two winding outputs. The two winding outputs are directly connected to inputs of a first filter and a second filter, respectively. When the amplifier operates in a frequency band of the first filter or the second filter, the first shunt switch and the second shunt switch are configured to transmit the unbalanced single signal from one of the two winding outputs to a corresponding filter, and to shunt the other filter to ground.

### RELATED APPLICATIONS

This application claims the benefit of provisional patent application Ser. No. 63/635,171, filed Apr. 17, 2024, the disclosure of which is hereby incorporated herein by reference in its entirety.

### FIELD OF THE DISCLOSURE

The present disclosure relates to a dual-band reconfigurable balun circuit, which provides balanced to unbalanced signal conversion with impedance tuning for dual frequency bands in a radio frequency (RF) communication module.

### BACKGROUND

In many radio frequency (RF) communication applications, balanced (or differential) to unbalanced signal conversion is highly desired, which enables connecting a balanced system such as differential amplifiers to an unbalanced system such as an antenna or a coaxial cable. An essential signal conversion component used in RF communication applications is a balanced to unbalanced transformer or a balun circuit. The balun circuit is employed for matching an optimal impedance at a differential power amplifier (PA) output to a desired impedance level of an antenna. Therefore, impedance tuning capability is a desirable feature of the balun circuit.

In the current generation of front-end module solutions for RF communication applications, separate PA dies and separate balun circuits are used for different frequency bands. However, using separate PA dies and separate balun circuits results in larger device sizes and higher costs.

Accordingly, there remains a need for improved balun circuit designs, which can accommodate dual frequency bands and are capable of impedance tuning, so as to reduce the size of a device and achieve an accurate impedance match. In addition, there is also a need to keep the final product cost-effective.

### SUMMARY

The present disclosure relates to a dual-band reconfigurable balun circuit, which provides balanced to unbalanced signal conversion with impedance tuning for dual frequency bands in a radio frequency (RF) communication module. The disclosed dual-band reconfigurable balun circuit includes a transformer structure, a first shunt switch, and a second shunt switch. Herein, the transformer structure includes a primary winding and a secondary winding with a first winding output and a second winding output, the first shunt switch is coupled between the first winding output and ground, and the second shunt switch is coupled between the second winding output and ground. The primary winding receives a pair of differential signals from an amplifier, and the secondary winding provides an unbalanced single signal at either the first winding output or the second winding output. The first winding output is directly connected to an input of a first filter, and the second winding output is directly connected to an input of a second filter. When the amplifier operates in a frequency band of the first filter, the first shunt switch is open and the second shunt switch is closed, such that the unbalanced single signal is transmitted from the first winding output to the first filter, and the second winding output and the second filter are shunted to ground via the closed second shunt switch. When the amplifier operates in a frequency band of the second filter, the second shunt switch is open and the first shunt switch is closed, such that the unbalanced single signal is transmitted from the second winding output to the second filter, and the first winding output and the first filter are shunted to ground via the closed first shunt switch.

In one embodiment of the dual-band reconfigurable balun circuit, the transformer structure further includes a first tuning capacitor and a second tuning capacitor. Herein, the first tuning capacitor is parallel to the first shunt switch and coupled between the first winding output and ground, while the second tuning capacitor is parallel to the second shunt switch and coupled between the second winding output and ground. When the amplifier operates in the frequency band of the first filter, the first tuning capacitor contributes to an output impedance of the dual-band reconfigurable balun circuit, and the second tuning capacitor is shunted to ground via the closed second shunt switch. When the amplifier operates in the frequency band of the second filter, the second tuning capacitor contributes to the output impedance of the dual-band reconfigurable balun circuit, and the first tuning capacitor is shunted to ground via the closed first shunt switch.

In one embodiment of the dual-band reconfigurable balun circuit, the first tuning capacitor and the second tuning capacitor have different capacitances.

In one embodiment of the dual-band reconfigurable balun circuit, the first shunt switch has a first parasitic off-state capacitance, and the second shunt switch has a second parasitic off-state capacitance. When the amplifier operates in the frequency band of the first filter, the first parasitic off-state capacitance of the first shunt switch contributes to an output impedance of the dual-band reconfigurable balun circuit. When the amplifier operates in the frequency band of the second filter, the second parasitic off-state capacitance of the second shunt switch contributes to the output impedance of the dual-band reconfigurable balun circuit.

In one embodiment of the dual-band reconfigurable balun circuit, the first parasitic off-state capacitance is different from the second parasitic off-state capacitance.

In one embodiment of the dual-band reconfigurable balun circuit, the transformer structure further includes a common tuning capacitor coupled between the first winding output and the second winding output. Regardless of the amplifier operating in the frequency band of the first filter or the frequency band of the second filter, the common tuning capacitor contributes to the output impedance of the dual-band reconfigurable balun circuit.

In one embodiment of the dual-band reconfigurable balun circuit, the transformer structure further includes one or more decoupling capacitors, which are coupled between a midpoint of the primary winding and ground.

According to one embodiment, the dual-band reconfigurable balun circuit further includes a tuning capacitance structure, which is coupled between the first winding output and ground, and/or coupled between the second winding output and ground. The tuning capacitance structure is configured to individually tune the output impedance of the dual-band reconfigurable balun circuit for the frequency band of the first filter and the frequency band of the second filter.

In one embodiment of the dual-band reconfigurable balun circuit, the tuning capacitance structure includes at least one first additional tuning capacitor, at least one first tuning switch, at least one second additional tuning capacitor, and at least one second tuning switch. The at least one first additional tuning capacitor and the at least one first tuning switch are coupled in series between the first winding output and ground, while the at least one second additional tuning capacitor and the at least one second tuning switch are coupled in series between the second winding output and ground.

In one embodiment of the dual-band reconfigurable balun circuit, the at least one first additional tuning capacitor and the at least one second additional tuning capacitor have different capacitances.

In one embodiment of the dual-band reconfigurable balun circuit, the at least one first additional tuning capacitor includes a number of first additional tuning capacitors, and the at least one first tuning switch includes a number of first tuning switches. The at least one second additional tuning capacitor includes a number of second additional tuning capacitors, and the at least one second tuning switch includes a number of second tuning switches. Herein, each of the first additional tuning capacitors and a corresponding one of the first tuning switches are coupled in series between the first winding output and ground, while each of the second additional tuning capacitors and a corresponding one of the second tuning switches are coupled in series between the second winding output and ground.

In one embodiment of the dual-band reconfigurable balun circuit, by selectively closing different numbers of the first tuning switches, a first combined capacitance between the first winding output and ground is varied in a first range. By selectively closing different numbers of the second tuning switches, a second combined capacitance between the second winding output and ground is varied in a second range. The first range can be the same as or different from the second range.

In one embodiment of the dual-band reconfigurable balun circuit, the tuning capacitance structure includes a number of first programmable switches and a number of second programmable switches. Herein, each of the first programmable switches and each of the second programmable switches has a parasitic off-state capacitance. The first programmable switches are coupled in series between the first winding output and ground, while the second programmable switches are coupled in series between the second winding output and ground.

In one embodiment of the dual-band reconfigurable balun circuit, by selectively turning off different numbers of the first programmable switches, a first combined parasitic capacitance between the first winding output and ground is varied in a first range. By selectively turning off different numbers of the second programmable switches, a second combined parasitic capacitance between the second winding output and ground is varied in a second range. Herein the first range can be the same as or different from the second range.

According to another embodiment, an alternative dual-band reconfigurable balun circuit includes a transformer structure, a first series switch, a second series switch, and a tuning capacitance structure. Herein, the transformer structure includes a primary winding and a secondary winding with a first winding output and a second winding output, the first series switch is coupled between the first winding output and an input of a first filter, the second series switch is coupled between the second winding output and an input of a second filter, and the tuning capacitance structure is coupled between the first winding output and ground, and/or coupled between the second winding output and ground. The primary winding of the transformer structure receives a pair of differential signals from an amplifier, and the secondary winding provides an unbalanced single signal at either the first winding output or the second winding output. When the amplifier operates in a frequency band of the first filter, the first series switch is closed and the second series switch is open, such that the unbalanced single signal is transmitted from the first winding output to the first filter through the closed first series switch, and the second winding output is isolated from the second filter by the open second series switch. When the amplifier operates in a frequency band of the second filter, the second series switch is closed and the first series switch is open, such that the unbalanced single signal is transmitted from the second winding output to the second filter through the closed second series switch, and the first winding output is isolated from the first filter by the open first series switch. The tuning capacitance structure is configured to individually tune the output impedance of the alternative dual-band reconfigurable balun circuit for the frequency band of the first filter and the frequency band of the second filter.

In one embodiment of the alternative dual-band reconfigurable balun circuit, the tuning capacitance structure includes at least one first additional tuning capacitor, at least one first tuning switch, at least one second additional tuning capacitor, and at least one second tuning switch. The at least one first additional tuning capacitor and the at least one first tuning switch are coupled in series between the first winding output and ground, while the at least one second additional tuning capacitor and the at least one second tuning switch are coupled in series between the second winding output and ground.

In one embodiment of the alternative dual-band reconfigurable balun circuit, the at least one first additional tuning capacitor and the at least one second additional tuning capacitor have different capacitances.

In one embodiment of the alternative dual-band reconfigurable balun circuit, the at least one first additional tuning capacitor includes a number of first additional tuning capacitors and the at least one first tuning switch includes a number of first tuning switches. The at least one second additional tuning capacitor includes a number of second additional tuning capacitors and the at least one second tuning switch includes a number of second tuning switches. Herein, each of the first additional tuning capacitors and a corresponding one of the first tuning switches are coupled in series between the first winding output and ground. Each of the second additional tuning capacitors and a corresponding one of the second tuning switches are coupled in series between the second winding output and ground.

In one embodiment of the alternative dual-band reconfigurable balun circuit, by selectively closing different numbers of the first tuning switches, a first combined capacitance between the first winding output and ground is varied in a first range. By selectively closing different numbers of the second tuning switches, a second combined capacitance between the second winding output and ground is varied in a second range. The first range can be the same as or different from the second range.

In one embodiment of the alternative dual-band reconfigurable balun circuit, the tuning capacitance structure includes a number of first programmable switches and a number of second programmable switches. Herein, each of the first programmable switches and each of the second programmable switches has a parasitic off-state capacitance. The first programmable switches are coupled in series between the first winding output and ground, and the second programmable switches are coupled in series between the second winding output and ground.

In one embodiment of the alternative dual-band reconfigurable balun circuit, by selectively turning off different numbers of the first programmable switches, a first combined parasitic capacitance between the first winding output and ground is varied in a first range. By selectively turning off different numbers of the second programmable switches, a second combined parasitic capacitance between the second winding output and ground is varied in a second range. The first range can be the same as or different from the second range.

In one embodiment of the alternative dual-band reconfigurable balun circuit, the transformer structure further includes a first tuning capacitor and a second tuning capacitor. Herein, the first tuning capacitor is coupled between the first winding output and ground, and the second tuning capacitor is coupled between the second winding output and ground. The first tuning capacitor and the second tuning capacitor simultaneously contribute to the output impedance of the dual-band reconfigurable balun circuit regardless of whether the amplifier operates in the frequency band of the first filter or the frequency band of the second filter.

According to one embodiment, the alternative dual-band reconfigurable balun circuit further includes a first shunt switch and a second shunt switch. The first shunt switch is coupled between the input of the first filter and ground, and the second shunt switch is coupled between the input of the second filter and ground. Herein, when the amplifier operates in the frequency band of the first filter, the first shunt switch is open and the second shunt switch is closed, such that the second filter is shunted to ground via the closed second shunt switch. When the amplifier operates in the frequency band of the second filter, the second shunt switch is open and the first shunt switch is closed, such that the first filter is shunted to ground via the closed first shunt switch.

According to one embodiment, a radio frequency (RF) communication module includes an amplifier, dual filters including a first filter and a second filter, antenna switching circuitry (ASW) following the dual filters, and a dual-band reconfigurable balun circuit coupled between the amplifier and the dual filters. The dual-band reconfigurable balun circuit includes the transformer structure having a primary winding and a secondary winding with a first winding output and a second winding output, the first series switch is coupled between the first winding output and an input of the first filter, the second series switch is coupled between the second winding output and an input of the second filter, and the tuning capacitance structure is coupled between the first winding output and ground, and/or coupled between the second winding output and ground. The primary winding of the transformer structure receives a pair of differential signals from an amplifier, and the secondary winding provides an unbalanced single signal at either the first winding output or the second winding output. When the amplifier operates in a frequency band of the first filter, the first series switch is closed and the second series switch is open, such that the unbalanced single signal is transmitted from the first winding output to the first filter through the closed first series switch, and the second winding output is isolated from the second filter by the open second series switch. When the amplifier operates in a frequency band of the second filter, the second series switch is closed and the first series switch is open, such that the unbalanced single signal is transmitted from the second winding output to the second filter through the closed second series switch, and the first winding output is isolated from the first filter by the open first series switch. The tuning capacitance structure is configured to individually tune the output impedance of the alternative dual-band reconfigurable balun circuit for the frequency band of the first filter and the frequency band of the second filter.

According to one embodiment, a method, operating in a dual-band reconfigurable balun circuit that is coupled between an amplifier and dual filters and includes a transformer structure and a plurality of switches, starts with determining a frequency band in which the amplifier provides a pair of balanced signals to the transformer structure. Next, one of two winding outputs of the transformer structure is determined to transmit an unbalanced single signal to a corresponding one of the dual filters based on the determined frequency band. A number of switches, which are between the winding outputs and the dual filters, are programmed to turn on/off, so as to ensure that the unbalanced single signal is capable of being transmitted to the corresponding one of the dual filters, and an output impedance of the dual-band reconfigurable balun circuit substantially matches an input impedance of the corresponding one of the dual filters. The pair of balanced signals from the amplifier are then converted to the unbalanced single signal and the unbalanced single signal is transmitted from the determined one of the winding outputs of the transformer structure to the corresponding one of the dual filters.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a radio frequency (RF) communication module including a typical balun circuit.

FIGS. 2A and 2B illustrate a conceptional block-level dual-sided molded Ball Grid Array (BGA) package (DSMBGA) for implementing the RF communication module shown in FIG. 1.

FIG. 3 illustrates an RF communication module including an exemplary dual-band reconfigurable balun circuit according to some embodiments of the present disclosure.

FIGS. 4A-7 illustrate an RF communication module including an alternative dual-band reconfigurable balun circuit according to some embodiments of the present disclosure.

FIGS. 8-9 illustrate an exemplary tuning capacitance structure within one dual-band reconfigurable balun circuit according to some embodiments of the present disclosure.

FIG. 10 illustrates a flowchart of an operating process of one dual-band reconfigurable balun circuit according to some embodiments of the present disclosure.

FIG. 11 illustrates a block diagram of a communication device that includes at least one dual-band reconfigurable balun circuit.

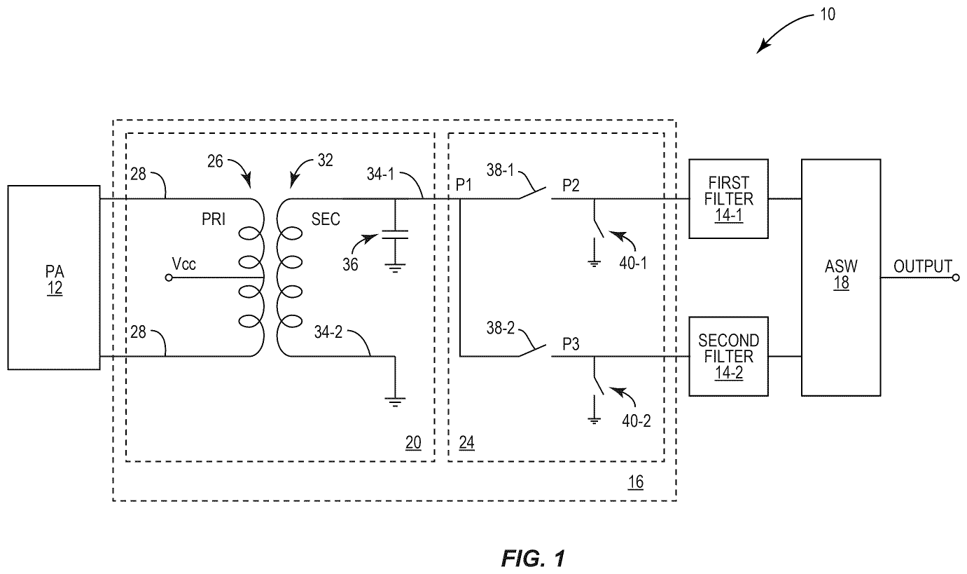

It will be understood that for clear illustrations, FIGS. 1-11 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

In a conventional radio frequency (RF) communication module solution, one power amplifier (PA), one filter, and one balun circuit coupled between the PA and the filter are needed for a specific frequency band. Thus, for dual-band applications, one RF communication module typically includes two separate PAs, two separate balun circuits, and two filters, which, however, results in a large module size and higher cost. To reduce the module size and cost, a dual-band configuration, which includes one PA and one balun, is desired. In a typical implementation, the PA and the balun circuit can cover both frequency bands, and the balun circuit utilizes one or more single-pole dual-throw (SPDT) switches coupled in series with filters to select a desired frequency band. As illustrated in FIG. 1, an RF communication module 10 includes a PA 12, two filters 14 (e.g., a first filter 14-1 and a second filter 14-2), a balun circuit 16 coupled between the PA 12 and the filters 14, and an antenna switching circuitry (ASW) 18 following the filters 14.

Herein, the balun circuit 16 includes a transformer structure 20, and a SPDT switch structure 24 coupled in series between the transformer structure 20 and the filters 14. The transformer structure 20 includes a primary winding 26 with two winding inputs 28, and a secondary winding 32 with two winding outputs 34 (e.g., a first winding output 34-1 and a second winding output 34-2), and a secondary capacitor 36. The PA 12 is connected to the two winding inputs 28 and configured to provide a pair of differential signals to the transformer structure 20. The transformer structure 20 may be a balanced-unbalanced transformer structure and configured to convert the differential signals into an unbalanced single signal. Within the transformer structure 20, a direct current (DC) voltage VCC is connected to a midpoint of the primary winding 26 and configured to provide a DC bias for the differential signals from the PA 12. The secondary capacitor 36 is coupled between the first winding output 34-1 and ground and contributes to an output impedance of the balun circuit 16 (i.e., a load impedance of the PA 12, seeing back from inputs of the filters 14). The second winding output 34-2 may be coupled to ground.

The SPDT switch structure 24 includes a first port P1 connected to the first winding output 34-1, and a second port P2 and a third port P3 connected to an input of the first filter 14-1 and an input of the second filter 14-2, respectively. The SPDT switch structure 24 utilizes two switch arms (e.g., a first switch arm 38-1 and a second switch arm 38-2) to selectively transmit the unbalanced single signal from the first winding output 34-1 to one of the filters 14. In addition, the SPDT switch structure 24 may also include two shunt switches 40 (e.g., a first shunt switch 40-1 and a second shunt switch 40-2) to improve isolation. When the PA 12 operates in a frequency passband of the first filter 14-1, the SPDT switch structure 24 is selected to connect the first port P1 to the second port P2 (i.e., the first switch arm 38-1 is conducted, while the second switch arm 38-2 is open), and the second shunt switch 40-2, which is connected to the second filter 14-2 is conducted to ground. As such, the first filter 14-1 is electrically connected to the transformer structure 20 and receives the unbalanced single signal converted from the differential signals of the PA 12, while the second filter 14-2 is shunted to ground. Similarly, when the PA 12 operates in a frequency passband of the second filter 14-2, the SPDT switch structure 24 is selected to connect the first port P1 to the third port P3 (i.e., the first switch arm 38-1 is open, while the second switch arm 38-2 is conducted), and the first shunt switch 40-1, which is connected to the first filter 14-1 is conducted to ground. As such, the second filter 14-2 is electrically connected to the transformer structure 20 and receives the unbalanced single signal converted from the differential signals of the PA 12, while the first filter 14-1 is shunted to ground. Each filter 14 is configured to filter the unbalanced single signal and transmit the filtered signal to an output of the RF communication module 10 (e.g., connecting to antennas, not shown) through the ASW 18.

It is noted that the RF communication module 10 provides a dual-band configuration solution with one PA 12 and one balun circuit 16, thereby reducing module size. However, the output impedance of the balun circuit 16 cannot be individually tuned for each frequency band of the filters 14 (to keep a high Q factor, the secondary capacitor 36 has a fixed capacitance). As such, the balun circuit 16 may not provide an optimal impedance match from the PA 12 to the different filters 14 and thereby to different antennas.

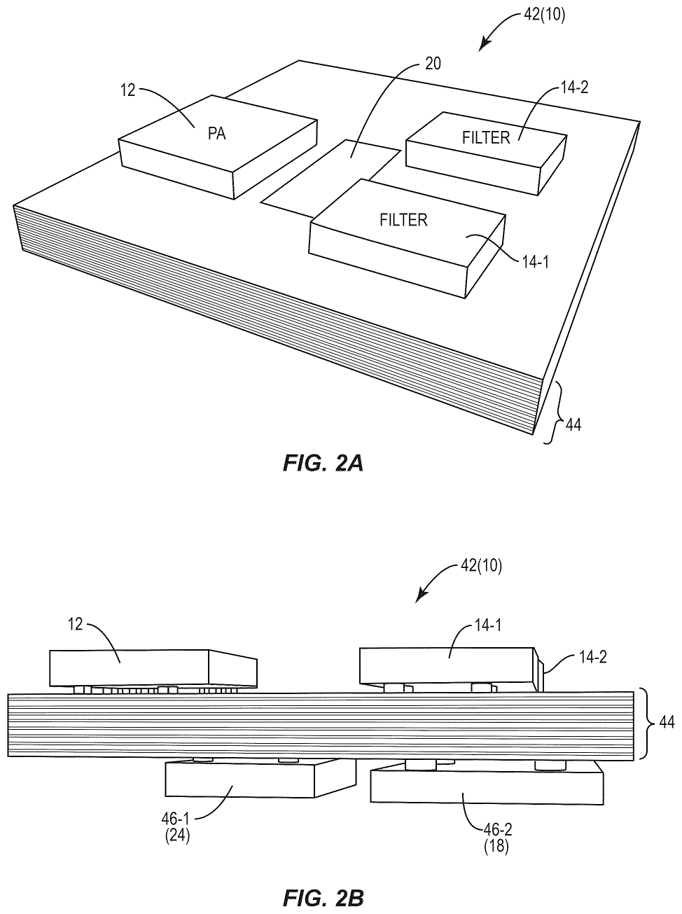

From fabrication aspects, the RF communication module 10 may be fabricated in a dual sided molded Ball Grid Array (BGA) package (DSMBGA) 42, as illustrated in FIGS. 2A-2B (other components in the DSMBGA are not shown for simplicity). FIG. 2A illustrates a top view of the DSMBGA 42, while FIG. 2B illustrates a side view of the DSMBGA 42. Typically, the PA 12 and the filters 14 are mounted on a top surface of a laminate 44, and the transformer structure 20 is implemented on multiple layers of the laminate 44. The SPDT switch structure 24 and the ASW 18 may be formed in silicon-on-isolator (SOI) dies 46 (e.g., a first SOI die 46-1 including the SPDT switch structure 24, and a second SOI die 46-2 including the ASW 18), which are typically mounted on a bottom surface of the laminate 44. In the DSMBGA 42, the unbalanced single signal output from the transformer structure 20 needs to be routed to the bottom surface of the laminate (e.g., to the first SOI die including the SPDT switch structure 24) and routed back to the top surface of the laminate (e.g., to the filter 14-1/14-2), which may result in additional signal degradation and signal crosstalk.

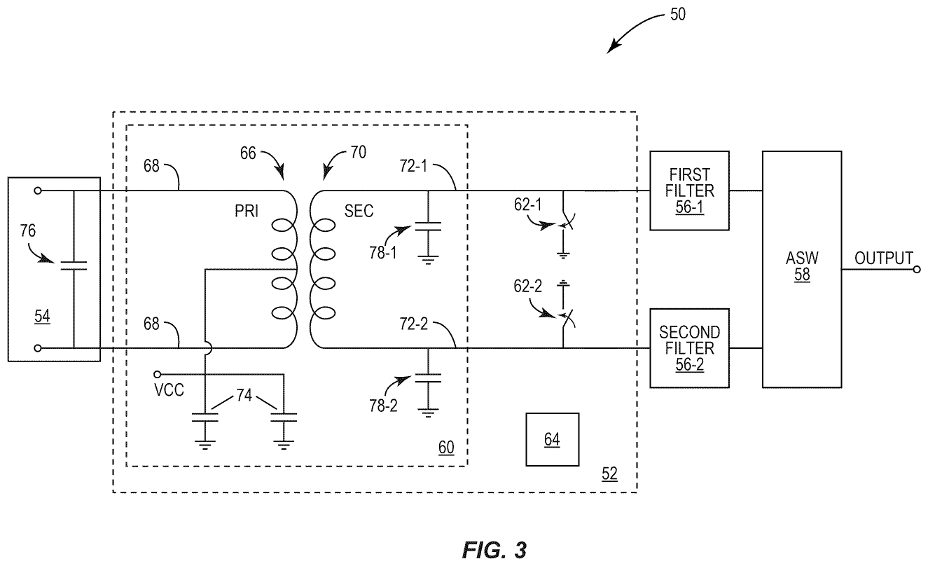

To improve impedance tuning capability and/or shorten signal routing, the present disclosure proposes a new configuration of one balun circuit. FIG. 3 illustrates an RF communication module 50 including an exemplary dual-band reconfigurable balun circuit 52, which has improvements in impedance tuning and shortens signal routing, according to some embodiments of the present disclosure. Besides the dual-band reconfigurable balun circuit 52, the RF communication module 50 further includes an amplifier 54 (e.g., a PA), two filters 56 (e.g., a first filter 56-1 and a second filter 56-2), and an ASW 58 with one or more switches (not shown). The dual-band reconfigurable balun circuit 52 is coupled between the amplifier 54 and the filters 56, and the ASW 58 follows the filters 56.

In detail, the dual-band reconfigurable balun circuit 52 includes a transformer structure 60, two shunt switches 62 (e.g., a first shunt switch 62-1 and a second shunt switch 62-2), and a control component 64 configured to control ON/OFF states of the shunt switches 62 (connection between the control component 64 and the shunt switches 62 is not shown for simplicity). The transformer structure 60 includes a primary winding 66 with two winding inputs 68, a secondary winding 70 with two winding outputs 72 (e.g., a first winding output 72-1 and a second winding output 72-2), and decoupling capacitors 74. The amplifier 54 is connected to the two winding inputs 68 and configured to provide a pair of differential signals to the transformer structure 60. The amplifier 54 may include a primary tuning capacitor 76 coupled between the two winding inputs 68 of the primary winding 66 and is configured to provide an impedance match from an output of the amplifier 54 to an input of the dual-band reconfigurable balun circuit 52. The amplifier 54 may be fabricated with gallium arsenide technology and the primary tuning capacitor 76 may be a metal-insulator-metal (MIM) capacitor. The amplifier 54 may be any type of PA as long as it provides differential signals, such as a linear PA, an envelope tracking (ET) PA, a Doherty PA, a load modulated PA, etc.

The transformer structure 60 is a balanced-unbalanced transformer structure and is configured to convert the differential signals from the amplifier 54 (via the two winding inputs 68) into two unbalanced single signals at the first winding output 72-1 and the second winding output 72-2, respectively (at a given time, only one unbalanced single signal will transmit towards the output of the RF communication module 50, more details are described below). Within the transformer structure 60, a DC voltage supply Vcc is applied to the midpoint of the primary winding 66, so as to provide a DC bias for the differential signals from the amplifier 54. The decoupling capacitors 74, which are parallel to each other and coupled between the midpoint of the primary winding 66 and ground, are configured to decouple the DC voltage from the RF signals by providing a low impedance at the midpoint of the primary winding 66. In addition, the transformer structure 60 also includes a first tuning capacitor 78-1 coupled between the first winding output 72-1 of the secondary winding 70 and ground, and a second tuning capacitor 78-2 coupled between the second winding output 72-2 of the secondary winding 70 and ground. Each tuning capacitor 78 can contribute to an output impedance of the dual-band reconfigurable balun circuit 52 (i.e., a load impedance of the amplifier 50, seeing back from inputs of the filters 56). To keep the high Q factor, both the first tuning capacitor 78-1 and the second tuning capacitor 78-2 have fixed capacitances and may be surface mounted device (SMD) capacitors.

Different from the typical transformer structure 20 that only provides the unbalanced single signal at one winding output (e.g., the first winding output 34-1), the transformer structure 60 is capable of providing the unbalanced single signal at either of the first winding output 72-1 and the second winding output 72-2. Herein, the first winding output 72-1 is directly connected to an input of the first filter 56-1, while the second winding output 72-2 is directly connected to an input of the second filter 56-2. The first shunt switch 62-1 is coupled between the input of the first filter 56-1 and ground (e.g., parallel to the first tuning capacitor 78-1), and the second shunt switch 62-2 is coupled between the input of the second filter 56-2 and ground (e.g., parallel to the second tuning capacitor 78-2). Each of the first shunt switch 62-1 and the second shunt switch 62-2 has a parasitic off-state capacitance, which can also contribute to an output impedance of the dual-band reconfigurable balun circuit 52.

The RF communication module 50 might be an ultra-high-band (UHB) cellular front-end module, where the amplifier 54 drives two filter paths (e.g., the first and second filters 56-1 and 56-2 are two transmitter filters) for two different frequency bands. When the amplifier 54 operates in a frequency passband of the first filter 56-1 (e.g., n77 frequency band, 3.3 GHZ-4.2 GHZ), the first shunt switch 62-1 is controlled to be open and the second shunt switch 62-2 is controlled to be closed (i.e., forming a shunt line to ground). As such, the unbalanced single signal provided at the first winding output 72-1 is transmitted to the first filter 56-1, while the unbalanced single signal provided at the second winding output 72-2 is transmitted to ground and cannot be transmitted to the second filter 56-2. In this scenario, the first tuning capacitor 78-1 and the parasitic off-state capacitance of the first shunt switch 62-1 contribute to the output impedance of the dual-band reconfigurable balun circuit 52, while the second tuning capacitor 78-2 is shunted to ground via the closed second shunt switch 62-2 and has a negligible effect on the output impedance of the dual-band reconfigurable balun circuit 52. Similarly, when the amplifier 54 operates in a frequency passband of the second filter 56-2 (e.g., n79 frequency band, 4.4 GHZ-5 GHZ), the second shunt switch 62-2 is controlled to be open and the first shunt switch 62-1 is controlled to be closed (i.e., forming a shunt line to ground). As such, the unbalanced single signal provided at the second winding output 72-2 is transmitted to the second filter 56-2, while the unbalanced single signal provided at the first winding output 72-1 is transmitted to ground and cannot be transmitted to the first filter 56-1. In this scenario, the second tuning capacitor 78-2 and the parasitic off-state capacitance of the second shunt switch 62-2 contribute to the output impedance of the dual-band reconfigurable balun circuit 52, while the first tuning capacitor 78-1 is shunted to ground via the closed first shunt switch 62-1 and has a negligible effect on the output impedance of the dual-band reconfigurable balun circuit 52. Each filter 56 is configured to filter the unbalanced single signal and transmit the filtered signal to an output of the RF communication module 50 (e.g., connecting to antennas, not shown) through the ASW 58.

It is noted that by carefully selecting the capacitances of the first and second tuning capacitors 78-1 and 78-2 and by designing the parasitic off-state capacitances of the first and second shunt switches 62-1 and 62-2, the dual-band reconfigurable balun circuit 52 is capable of providing different output impedances for different frequency bands. In consequence, the dual-band reconfigurable balun circuit 52 is capable of providing an optimal impedance match from the amplifier 54 to different filters 56, and thereby to different antennas. The first tuning capacitor 78-1 and the second tuning capacitor 78-2 may have different capacitances, and the parasitic off-state capacitance of the first shunt switch 62-1 and the parasitic off-state capacitance of the second shunt switch 62-2 might be different.

The RF communication module 50 can be used for time division duplexing (TDD) systems and/or frequency division duplexing (FDD) systems. For a TDD system, the RF communication module 50 can provide two filtering paths for two transmitters (TXs), each operating in a different frequency band: one path from the amplifier 54, through the first filter 56-1, to the ASW 58, and another path from the amplifier 54, through the second filter 56-2, to the ASW 58. Each receiver (RX) within the TDD system, which operates in a same frequency band as a corresponding TX, will utilize a separate receiver filter coupled to the ASW 58 (not shown) other than the first/second filter 56-1/56-2. Additionally, the ASW 58 may include additional switches to selectively connect between the filters (e.g., the first and second filters 56-1 and 56-2, and the receiver filters) and the antennas (not shown). For an FDD system, the first filter 56-1 and the second filter 56-2 are duplexer filters, each capable of supporting a pair of TX and RX operating in different frequencies.

In a case that the RF communication module 50 is fabricated in a DSMBGA (similar as the DSMBGA 42 shown in the FIGS. 2A and 2B, where the transformer structure 60 and the filters 56 are mounted on a same top surface of one laminate, while the shunt switches 62 are mounted on an opposite bottom surface of the laminate), the unbalanced single signal transmitted from the transformer structure 60 to either filter 56 does not need to be routed to the bottom surface of the laminate and routed back to the top surface of the laminate. Instead, the unbalanced single signal can be directly routed from either the first winding output 72-1 or the second winding output 72-2 of the transformer structure 60 to a corresponding filter 56 at the top surface of the laminate. The unbalanced single signal shunted to ground (through one shunt switch 62) only needs to be routed to the bottom surface of the laminate, but not be routed back to the top surface of the laminate. Therefore, signal degradation and/or signal crosstalk can be improved. In addition, if the RF communication module 50 is implemented with silicon germanium (SiGe) and heterojunction bipolar transistors (HBTs) dies, each shunt switch 62 can be implemented by connecting a collector to ground, an emitter to an RF node, and injecting current into a base to create a low on-state resistance (RON) between the RF node and ground. Furthermore, a physical distance between the first tuning capacitor 78-1 and the first shunt switch 62-1 and a physical distance between the second tuning capacitor 78-2 and the second shunt switch 62-2 need to be carefully designed, which results in electrical delays and thereby affects electrical properties of the dual-band reconfigurable balun circuit 52.

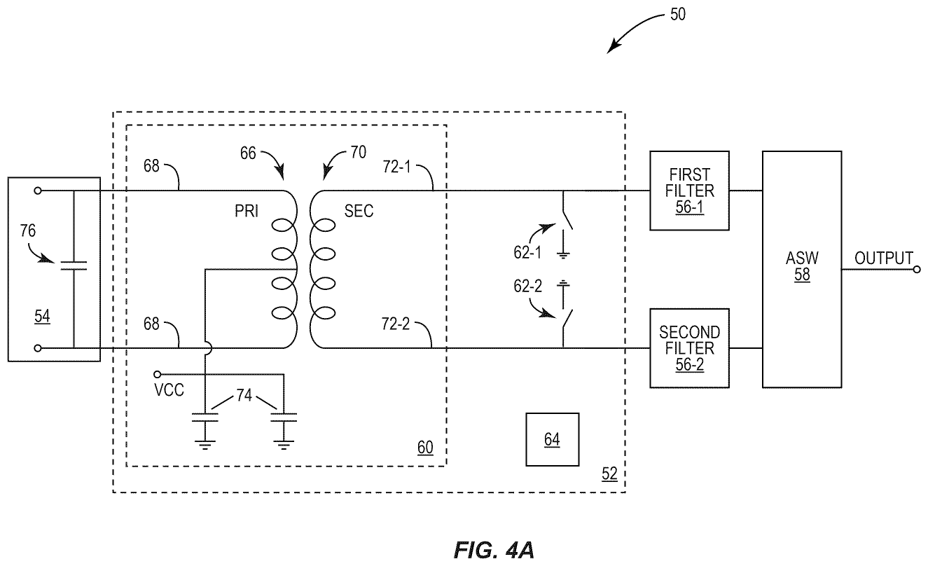

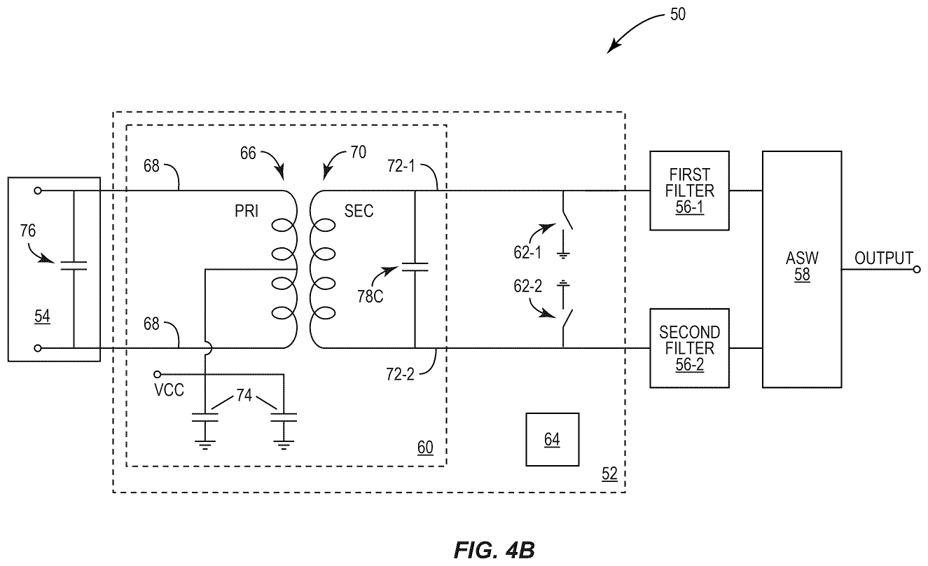

In some applications, the shunt switches 62 might be large switches and have relatively large parasitic off-state capacitances. Accordingly, one or both tuning capacitors 78 might be omitted. As illustrated in FIG. 4A, both the tuning capacitors 78 are omitted, and the shunt switches 62 are utilized not only to select which filter 56 is connected to the transformer structure 60, but also to adjust the output impedance of the dual-band reconfigurable balun circuit 52. When the amplifier 54 operates in the frequency passband of the first filter 56-1 (e.g., n77 frequency band), the first shunt switch 62-1 is controlled to be open and the second shunt switch 62-2 is controlled to be closed (i.e., forming the shunt line to ground). As such, the unbalanced single signal provided at the first winding output 72-1 is transmitted to the first filter 56-1, while the unbalanced single signal provided at the second winding output 72-2 is transmitted to ground and cannot be transmitted to the second filter 56-2. In this scenario, the parasitic off-state capacitance of the open first shunt switch 62-1 contributes to the output impedance of the dual-band reconfigurable balun circuit 52. Similarly, when the amplifier 54 operates in a frequency passband of the second filter 56-2 (e.g., n79 frequency band), the second shunt switch 62-2 is controlled to be open and the first shunt switch 62-1 is controlled to be closed (i.e., forming the shunt line to ground). As such, the unbalanced single signal provided at the second winding output 72-2 is transmitted to the second filter 56-2, while the unbalanced single signal provided at the first winding output 72-1 is transmitted to ground and cannot be transmitted to the first filter 56-1. In this scenario, the parasitic off-state capacitance of the open second shunt switch 62-2 contributes to the output impedance of the dual-band reconfigurable balun circuit 52.

Herein, the dual-band reconfigurable balun circuit 52 is still capable of providing different output impedances for different frequency bands by carefully designing the first and second shunt switch 62-1 and 62-2 (the parasitic off-state capacitance of the first shunt switch 62-1 and the parasitic off-state capacitance of the second shunt switch 62-2 might be different). Therefore, the dual-band reconfigurable balun circuit 52 is capable of providing an optimal impedance match from the amplifier 54 to different antennas.

In some applications, the first tuning capacitor 78-1 and the second tuning capacitor 78-2 might be replaced by a common tuning capacitor 78C, which is coupled with the first winding output 72-1 and the second winding output 72-2, as illustrated in FIG. 4B. When the amplifier 54 operates in the frequency passband of the first filter 56-1 (e.g., n77 frequency band), the first shunt switch 62-1 is controlled to be open and the second shunt switch 62-2 is controlled to be closed (i.e., forming the shunt line to ground). As such, the unbalanced single signal provided at the first winding output 72-1 is transmitted to the first filter 56-1, while the unbalanced single signal provided at the second winding output 72-2 is transmitted to ground and cannot be transmitted to the second filter 56-2. In this scenario, the common tuning capacitor 78C and the parasitic off-state capacitance of the first shunt switch 62-1 contribute to the output impedance of the dual-band reconfigurable balun circuit 52. Similarly, when the amplifier 54 operates in a frequency passband of the second filter 56-2 (e.g., n79 frequency band), the second shunt switch 62-2 is controlled to be open and the first shunt switch 62-1 is controlled to be closed (i.e., forming the shunt line to ground). As such, the unbalanced single signal provided at the second winding output 72-2 is transmitted to the second filter 56-2, while the unbalanced single signal provided at the first winding output 72-1 is transmitted to ground and cannot be transmitted to the first filter 56-1. In this scenario, the common tuning capacitor 78C and the parasitic off-state capacitance of the open second shunt switch 62-2 contribute to the output impedance of the dual-band reconfigurable balun circuit 52.

Herein, the dual-band reconfigurable balun circuit 52 is still capable of providing different output impedances for different frequency bands by carefully designing the first and second shunt switch 62-1 and 62-2 (the parasitic off-state capacitance of the first shunt switch 62-1 and the parasitic off-state capacitance of the second shunt switch 62-2 might be different). Therefore, the dual-band reconfigurable balun circuit 52 is capable of providing an optimal impedance match from the amplifier 54 to different antennas. In addition, since the common tuning capacitor 78C always contributes to the output impedance of the dual-band reconfigurable balun circuit 52 (regardless of the amplifier 54 operating in either the frequency passband of the first filter 56-1 or the frequency passband of the second filter 56-2), the parasitic off-state capacitance of the first shunt switch 62-1 and the parasitic off-state capacitance of the second shunt switch 62-2 are not required to be designed to be large. As a result, the first shunt switch 62-1 and the second shunt switch 62-2 may not have much impact on insertion loss.

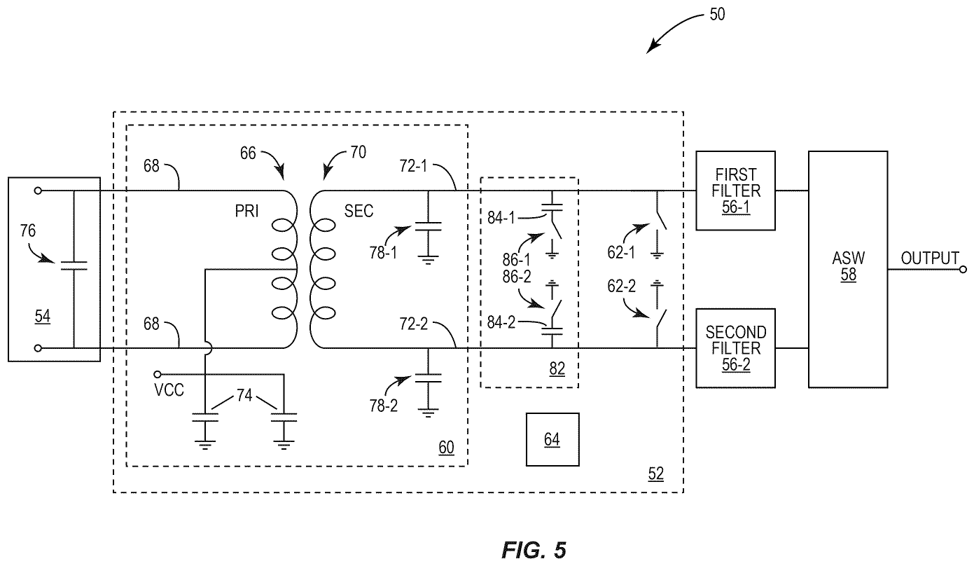

In some applications, individual impedance tuning is highly desired for different frequency bands or even for sub-bands within one frequency band. Thus, a tuning capacitance structure 82 is introduced in the dual-band reconfigurable balun circuit 52 for further/fine impedance tuning, as illustrated in FIG. 5. In addition to the shunt switches 62, the control component 64 is also configured to control impedance contribution from the tuning capacitance structure 82 to the output impedance of the dual-band reconfigurable balun circuit 52 (connection between the control component 64 and the tuning capacitance structure 82 is not shown for simplicity). The tuning capacitance structure 82 is coupled between the first winding output 72-1/the second winding output 72-2 and ground (i.e., between the first winding output 72-1 and ground, and/or between the second winding output 72-2 and ground). For the purpose of this illustration, the tuning capacitance structure 82 includes a first additional tuning capacitor 84-1 and a first tuning switch 86-1 coupled in series between the first winding output 72-1 and ground, and a second additional tuning capacitor 84-2 and a second tuning switch 86-2 coupled in series between the second winding output 72-2 and ground. The control component 64 is configured to control ON/OFF states of the tuning switches 86. In different applications, the tuning capacitance structure 82 may include fewer or more tuning capacitors 84 and/or fewer or more tuning switches 86 with different configurations.

Table I shows different ON/OFF states of each switch within the dual-band reconfigurable balun circuit 52 corresponding to different operating frequency bands.

TABLE I

| | Switch | Switch | Switch | Switch |
|---|---|---|---|---|
| | 62-1 | 86-1 | 62-2 | 86-2 |
| Frequency Band of | OFF | ON/OFF | ON | N/A |
| the First Filter 56-1 | | | | |
| Frequency Band of | ON | N/A | OFF | ON/OFF |
| the Second Filter 56-2 | | | | |

When the amplifier 54 operates in the frequency passband of the first filter 56-1 (e.g., n77 frequency band), the first shunt switch 62-1 is controlled to be open (i.e., OFF), and the second shunt switch 62-2 is controlled to be closed (i.e., ON). As such, the unbalanced single signal provided at the first winding output 72-1 is directly transmitted to the first filter 56-1, while the unbalanced single signal provided at the second winding output 72-2 cannot be transmitted to the second filter 56-2 but is shunted to ground through the closed second shunt switch 62-2. Herein, the first tuning capacitor 78-1 and the parasitic off-state capacitance of the first shunt switch 62-1 contribute to the output impedance of the dual-band reconfigurable balun circuit 52, and the first tuning switch 86-1 is controlled to be closed or open (i.e., ON/OFF) so as to determine whether to add the first additional tuning capacitor 84-1 to the output impedance or not. On the other hand, the second tuning capacitor 78-2 and the second additional tuning capacitor 84-2 (regardless of the ON/OFF state of the second tuning switch 86-2) are shunted to ground via the second shunt switch 62-2 and have a negligible effect on the output impedance of the dual-band reconfigurable balun circuit 52. Similarly, when the amplifier 54 operates in the frequency passband of the second filter 56-2 (e.g., n79 frequency band), the second shunt switch 62-2 is controlled to be open (i.e., OFF), and the first shunt switch 62-1 is controlled to be closed (i.e., ON). As such, the unbalanced single signal provided at the second winding output 72-2 is directly transmitted to the second filter 56-2, while the unbalanced single signal provided at the first winding output 72-1 cannot be transmitted to the first filter 56-1 but shunted to ground through the closed first shunt switch 62-1. Herein, the second tuning capacitor 78-2 and the parasitic off-state capacitance of the second shunt switch 62-2 contribute to the output impedance of the dual-band reconfigurable balun circuit 52, and the second tuning switch 86-2 is controlled to be closed or open (i.e., ON/OFF) so as to determine whether to add the second additional tuning capacitor 84-2 to the output impedance or not. The first tuning capacitor 78-1 and the first additional tuning capacitor 84-1 (regardless of the ON/OFF state of the first tuning switch 86-1) are shunted to ground via the first shunt switch 62-1 and have a negligible effect on the output impedance of the dual-band reconfigurable balun circuit 52.

It is clear that the tuning capacitance structure 82 provides extra flexibility in tuning the output impedance of the dual-band reconfigurable balun circuit 52. The first additional tuning capacitor 84-1 and the first tuning switch 86-1 are capable of further tuning the output impedance of the dual-band reconfigurable balun circuit 52 for the frequency band of the first filter 56-1, while the second additional tuning capacitor 84-2 and the second tuning switch 86-2 are capable of further tuning the output impedance of the dual-band reconfigurable balun circuit 52 for the frequency band of the second filter 56-2. The first additional tuning capacitor 84-1 and the second additional tuning capacitor 84-2 may have different capacitances. In addition, the tuning capacitance structure 82 can also be used to tune the inductance of one shunt line (i.e., formed by closing the first or second shunt switch 62) that connects to one winding output 72.

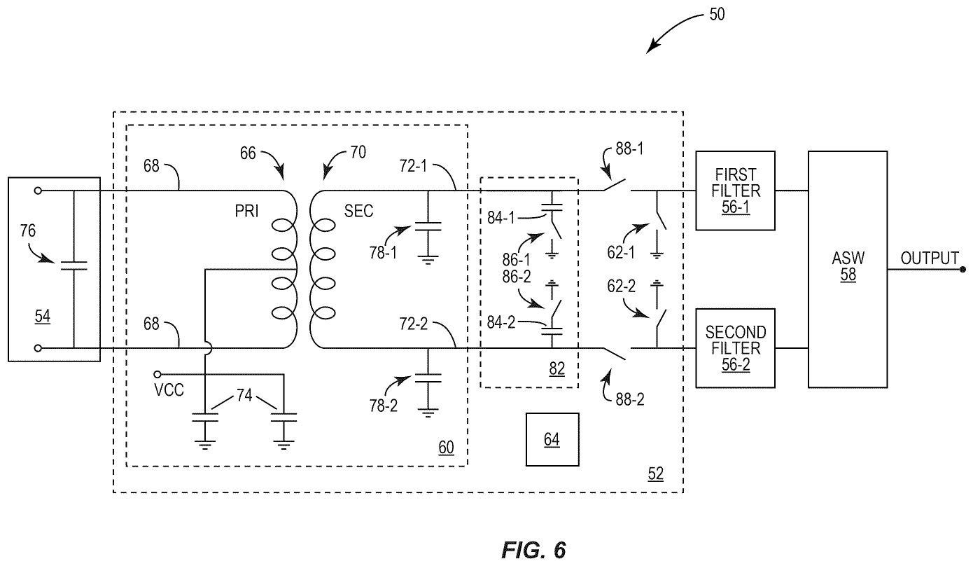

To provide better signal isolation between components and improve the utilization of the capacitors 78/84, series switches 88 (e.g., a first series switch 88-1 and a second series switch 88-2) are included in the dual-band reconfigurable balun circuit 52, as illustrated in FIG. 6. Herein, the first series switch 88-1 is coupled in series between the first winding output 72-1 and the first shunt switch 62-1 (i.e., between the first winding output 72-1 and the input of the first filter 56-1), while the second series switch 88-2 is coupled in series between the second winding output 72-2 and the second shunt switch 62-2 (i.e., between the second winding output 72-2 and the input of the second filter 56-2). The control component 64 is also configured to control ON/OFF states of the series switches 88 (connection between the control component 64 and the series switches 88 is not shown for simplicity).

Table II shows different ON/OFF states of each switch within the dual-band reconfigurable balun circuit 52 corresponding to different operating frequency bands.

TABLE II

| | Switch | Switch | Switch | Switch | Switch | Switch |
|---|---|---|---|---|---|---|
| | 62-1 | 88-1 | 86-1 | 62-2 | 88-2 | 86-2 |
| Frequency | OFF | ON | ON/ | ON | OFF | ON/ |
| Band of the | | | OFF | | | OFF |
| First Filter 56-1 | | | | | | |
| Frequency | ON | OFF | ON/ | OFF | ON | ON/ |
| Band of the | | | OFF | | | OFF |
| Second Filter | | | | | | |
| 56-2 | | | | | | |

Herein, when the amplifier 54 operates in the frequency passband of the first filter 56-1 (e.g., n77 frequency band), the first shunt switch 62-1 and the second series switch 88-2 are controlled to be open (i.e., OFF), and the first series switch 88-1 and the second shunt switch 62-2 are controlled to be closed (i.e., ON). As such, the unbalanced single signal provided at the first winding output 72-1 is transmitted to the first filter 56-1 through the closed first series switch 88-1, while the unbalanced single signal provided at the second winding output 72-2 cannot be transmitted to the second filter 56-2 due to the open second series switch 88-2. In addition, the second filter 56-2 is shunted to ground through the closed second shunt switch 62-2 and isolated from the transformer structure 60 by the open second series switch 88-2. Similarly, when the amplifier 54 operates in the frequency passband of the second filter 56-2 (e.g., n79 frequency band), the second shunt switch 62-2 and the first series switch 88-1 are controlled to be open (i.e., OFF), and the second series switch 88-2 and the first shunt switch 62-1 are controlled to be closed (i.e., ON). As such, the unbalanced single signal provided at the second winding output 72-2 is transmitted to the second filter 56-2 through the closed second series switch 88-2, while the unbalanced single signal provided at the first winding output 72-1 cannot be transmitted to the first filter 56-1 due to the open first series switch 88-1. The first filter 56-1 is shunted to ground through the closed first shunt switch 62-1 and isolated from the transformer structure 60 by the open first series switch 88-1. The series switches 88 also provide better isolations between the operating filter 56 and the unused filter 56.

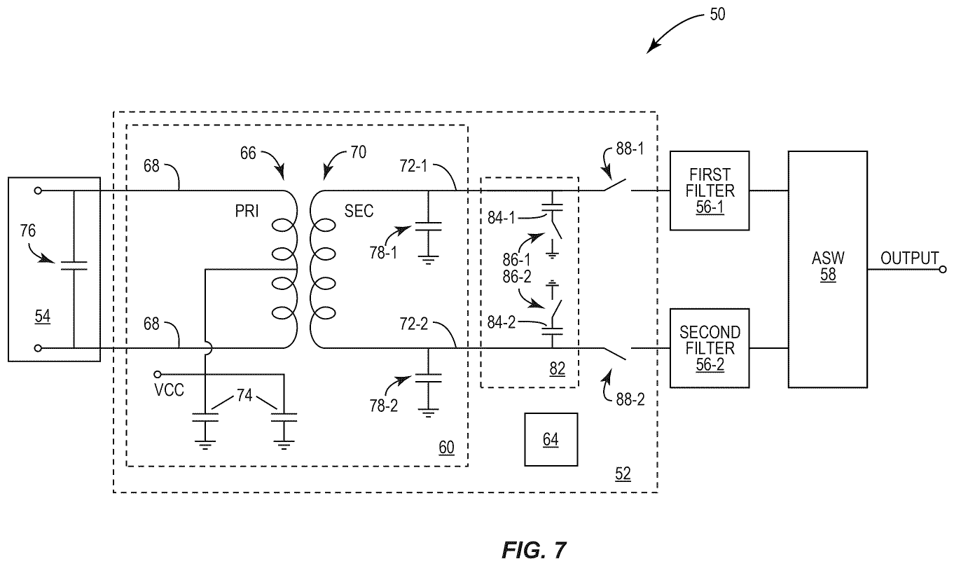

It is noted that by utilizing the series switches 88, both the first and second tuning capacitors 78 can simultaneously contribute to the output impedance of the dual-band reconfigurable balun circuit 52 (e.g., neither of the first and second tuning capacitors 78 is shunted to ground). In addition, the series switches 88 enable utilizing the first additional tuning capacitor 84-1 and the second additional tuning capacitor 84-2 simultaneously or separately (the additional tuning capacitors 84-1 and 84-2 are not shunted to ground through the shunt switches 62). By selectively closing/opening the first tuning switch 86-1 and the second tuning switch 86-2 within the tuning capacitance structure 82, the first additional tuning capacitor 84-1 and/or the second additional tuning capacitor 84-2 may be capable of contributing to the output impedance of the dual-band reconfigurable balun circuit 52 for different frequency bands or even different frequency sub-bands. In this illustration, there are four scenarios: both the first additional tuning capacitor 84-1 and the second additional tuning capacitor 84-2 contribute to an output impedance of the dual-band reconfigurable balun circuit 52 (i.e., both the first and second tuning switches 86-1 and 86-2 are closed), only the first additional tuning capacitor 84-1 contributes to the output impedance of the dual-band reconfigurable balun circuit 52 (i.e., the first tuning switch 86-1 is closed, and the second tuning switch 86-2 is open), only the second additional tuning capacitor 84-2 contributes to the output impedance of the dual-band reconfigurable balun circuit 52 (i.e., the first tuning switch 86-1 is open, and the second tuning switch 86-2 is closed), and neither the first additional tuning capacitor 84-1 nor the second additional tuning capacitor 84-2 contributes to the output impedance of the dual-band reconfigurable balun circuit 52 (i.e., both the first and second tuning switches 86-1 and 86-2 are open). Furthermore, with the series switches 88, the shunt switches 62 may be omitted in the dual-band reconfigurable balun circuit 52, as shown in FIG. 7. Table Ill shows different ON/OFF states of each switch (without the shunt switches 62) corresponding to different operating frequency bands.

TABLE III

| | Switch | Switch | Switch | Switch |
|---|---|---|---|---|
| | 88-1 | 86-1 | 88-2 | 86-2 |
| Frequency Band of the | ON | ON/OFF | OFF | ON/OFF |
| First Filter 56-1 | | | | |
| Frequency Band of the | OFF | ON/OFF | ON | ON/OFF |
| Second Filter 56-2 | | | | |

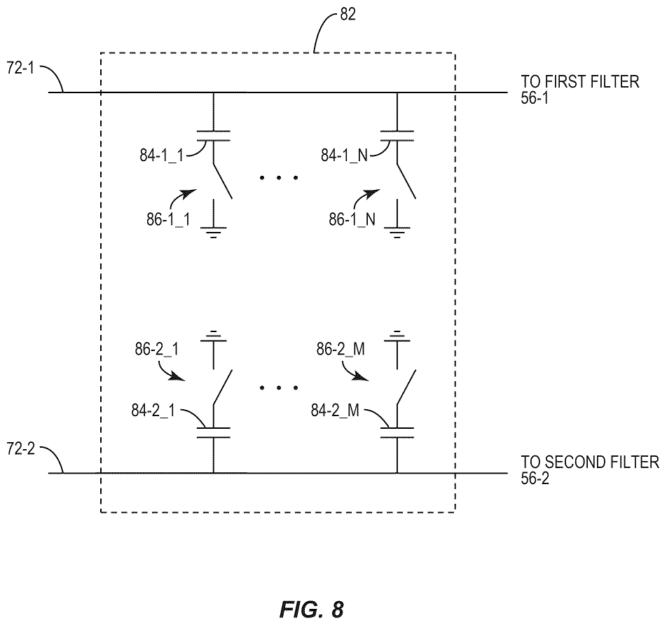

To further fine-tune the output impedance of the dual-band reconfigurable balun circuit 52, the tuning capacitance structure 82 may include more tuning capacitors 84 and more tuning switches 86, as illustrated in FIG. 8. Instead of one pair of the first additional tuning capacitor 84-1 and the first tuning switch 86-1 coupled between the first winding output 72-1 and ground, there are multiple pairs of one first additional tuning capacitor 84-1 and one first tuning switch 86-1 parallel to each other and coupled between the first winding output 72-1 and ground. Each of the first additional tuning capacitors 84-1 (e.g., the first additional tuning capacitors 84-1_1˜84-1_N) may have a same capacitance or a different capacitance. Similarly, there are multiple pairs of one second additional tuning capacitor 84-2 and one second tuning switch 86-2 parallel to each other and coupled between the second winding output 72-2 and ground. Each of the second additional tuning capacitors 84-2 (e.g., the second additional tuning capacitors 84-2_1˜84-2_M) may have a same capacitance or a different capacitance. The number of the first additional tuning capacitors 84-1 (the first tuning switches 86-1) and the number the second additional tuning capacitors 84-2 (the first tuning switches 86-2) may be the same or different.

The control component 64 is configured to control ON/OFF states of each tuning switch 86 (not shown) so as to provide a first combined capacitance between the first winding output 72-1 and ground and a second combined capacitance between the second winding output 72-2 and ground. By selectively closing/opening the first tuning switches 86-1 (e.g., the first tuning switches 86-1_1˜86-1_N) and the second tuning switches 86-2 (e.g., the second tuning switches 86-2_1˜86-2_N), the first combined capacitance and the second combined capacitance will have appropriate values and contribute to the output impedance of the dual-band reconfigurable balun circuit 52 for different frequency bands/sub-bands. A variation range of the first combined capacitance (by selectively closing/opening different numbers of the first tuning switches 86-1) and a variation range of the second combined capacitance (by selectively closing/opening different numbers of the second tuning switches 86-2) may be the same or different. The tuning capacitance structure 82 illustrated in FIG. 8 may be applied to the dual-band reconfigurable balun circuit 52 shown in FIGS. 5-7.

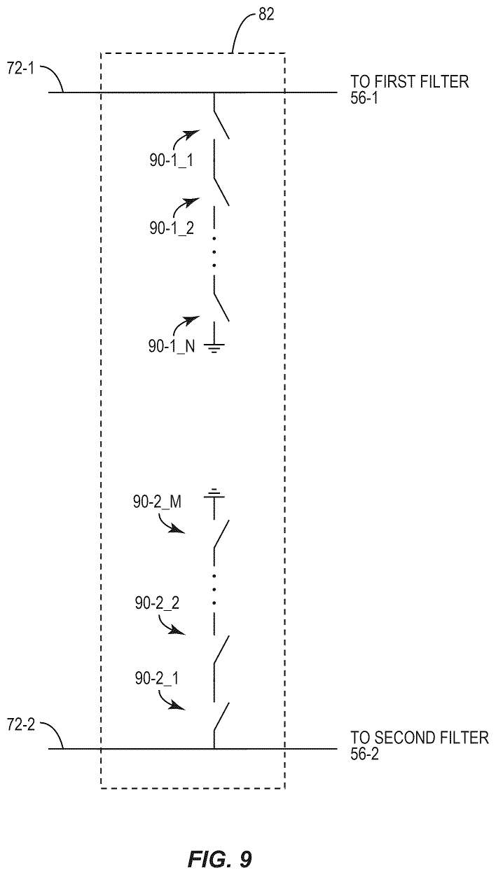

In some applications, switches themselves can be used to tune the output impedance of the dual-band reconfigurable balun circuit 52 by controlling the parasitic off-state capacitances of the switches. As illustrated in FIG. 9, the tuning capacitance structure 82 includes multiple first programmable switches 90-1 (e.g., the first programmable switches 90-1_1˜90-1_N) and multiple second programmable switches 90-2 (e.g., the second programmable switches 90-2_1˜90-2_M) without any tuning capacitor. Herein, the first programmable switches 90-1 are coupled in series between the first winding output 72-1 and ground, while the second programmable switches 90-2 are coupled in series between the second winding output 72-2 and ground. Each programmable switch 90 provides a parasitic capacitance in an OFF state (i.e., the switch is open). Due to device sizes (e.g., device finger widths, number of fingers, etc.), the parasitic off-state capacitance provided by each programmable switch 90 may be the same or different. For a non-limiting instance, when each first programmable switch 90-1 has a same parasitic capacitance C_{OFF1} and only three of the first programmable switches 90-1 are open, the combined parasitic capacitance of these three open programmable switches 90-1 is C_{OFF1}/3. For another non-limiting instance, when each second programmable switch 90-2 has a same parasitic capacitance C_{OFF2} and only two of the second programmable switches 90-2 are open, the combined parasitic capacitance of these two open second programmable switches 90-2 is C_{OFF2}/2.

The control component 64 is configured to control ON/OFF states of each programmable switch 90 (not shown), so as to provide a first combined parasitic capacitance between the first winding output 72-1 and ground and a second combined parasitic capacitance between the second winding output 72-2 and ground. By selectively controlling an appropriate number of the first programmable switches 90-1 and an appropriate number of the second programmable switches 90-2 to be closed, the first combined parasitic capacitance and the second combined parasitic capacitance will have appropriate values and contribute to the output impedance of the dual-band reconfigurable balun circuit 52 for different frequency bands/sub-bands. A variation range of the first combined parasitic capacitance (by selectively turning on/off different numbers of the first programmable switches 90-1) and a variation range of the second combined parasitic capacitance (by selectively turning on/off different numbers of the second programmable switches 90-2) may be the same or different. The number of the first programmable switches 90-1 and the number the second programmable switches 90-2 may be the same or different. The tuning capacitance structure 82 illustrated in FIG. 9 may be applied to the dual-band reconfigurable balun circuit 52 shown in FIGS. 5-7.

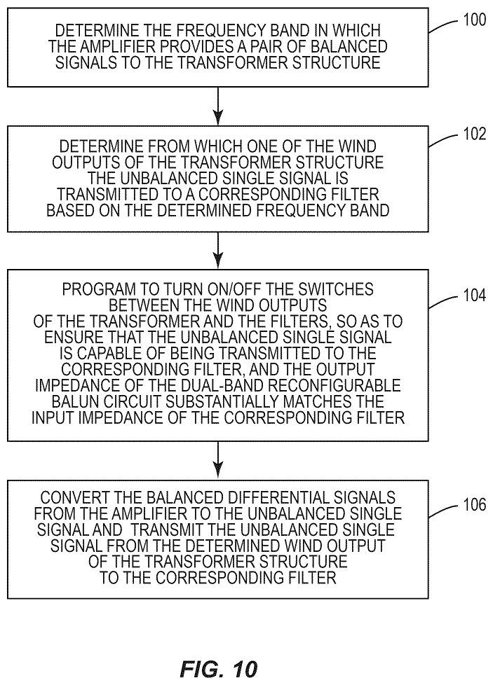

FIG. 10 illustrates a flowchart of an operating process of the dual-band reconfigurable balun circuit 52 according to some embodiments of the present disclosure. Although the process steps are illustrated in a series, the process steps are not necessarily order dependent. Some steps may be done in a different order than that presented. Further, processes within the scope of this disclosure may include fewer or more steps than those illustrated in FIG. 10. Initially, determine the frequency band in which the amplifier 54 provides a pair of balanced (differential) signals to the transformer structure 60 (step 100). Next, determine from which winding output 72 (e.g., either the first winding output 72-1 or the second winding output 72-2) of the transformer structure 60 the unbalanced single signal is transmitted to a corresponding filter 56 based on the determined frequency band (e.g., either the first filter 56-1 or the second filter 56-2, step 102). Herein, the first winding output 72-1 of the transformer structure 60 is coupled (directly or through the first series switch 88-1) to the input of the first filter 56-1, while the second winding output 72-2 of the transformer structure 60 is coupled (directly or through the second series switch 88-2) to the input of the second filter 56-2. Once the operating frequency band and the transmitting winding output 72 of the transformer structure 60 is determined, the switches (e.g., the shunt switches 62, the tuning switches 86, the series switches 88, and/or the programmable switches 90) between the winding outputs 72 of the transformer structure 60 and the inputs of the filters 56 are programmed to be turned ON/OFF (step 104). As such, the unbalanced single signal is capable of being transmitted to the corresponding filter 56, and the output impedance of the dual-band reconfigurable balun circuit 52 substantially matches the input impedance of the corresponding filter 56. After the switches are turned to the appropriate ON/OFF states, the balanced (differential) signals from the amplifier 54 are converted to the unbalanced single signal and the unbalanced single signal is transmitted from the determined winding output 72 of the transformer structure 60 to the corresponding filter 56 (step 106).

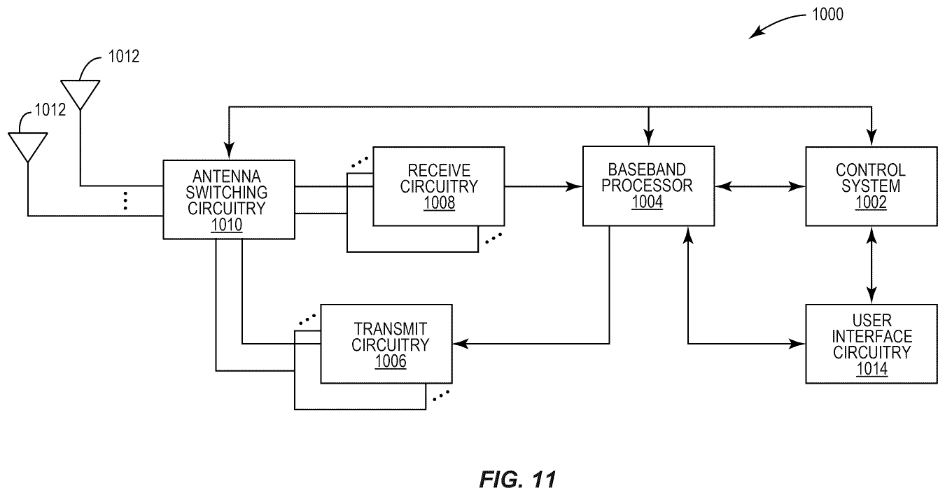

FIG. 11 illustrates a block diagram of an example communication device 1000 that includes at least one dual-band reconfigurable balun circuit that is capable of providing balanced to unbalanced signal conversion with impedance tuning for dual frequency bands as described above. The concepts described above may be implemented in various types of communication devices, such as mobile terminals, smart watches, tablets, computers, navigation devices, access points, and like wireless communication devices that support wireless communications, such as cellular, wireless local area network (WLAN), BLUETOOTH, and near field communications. The communication device 1000 will generally include a control system 1002, a baseband processor 1004, transmit circuitry 1006, receive circuitry 1008, antenna switching circuitry 1010 (similar to the ASW 58), multiple antennas 1012, and user interface circuitry 1014. In a non-limiting example, the control system 1002 can be a field-programmable gate array (FPGA) or an application-specific integrated circuit (ASIC), as an example. In this regard, the control system 1002 can include at least a microprocessor(s), an embedded memory circuit(s), and a communication bus interface(s). The receive circuitry 1008 receives radio frequency signals via the antennas 1012 and through the antenna switching circuitry 1010 from one or more base stations. Herein, the radio frequency signals might be unbalanced single signals. The receive circuitry 1008 is configured to convert the radio frequency signals from an unbalanced version to a balanced differential version, amplify, and remove broadband interference from the received signals for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 1004 processes the digitized received signal to extract the information or data bits conveyed in the received signal. This processing typically comprises demodulation, decoding, and error correction operations, as will be discussed in greater detail below. The baseband processor 1004 is generally implemented in one or more digital signal processors (DSPs) and ASICs.

For transmission, the baseband processor 1004 receives digitized data, which may represent voice, data, or control information, from the control system 1002, which is encoded for transmission. The encoded data is output to the transmit circuitry 1006, where a digital-to-analog converter(s) (DAC) converts the digitally encoded data into an analog signal and a modulator modulates the analog signal onto a carrier signal that is at a desired transmit frequency or frequencies. Herein, the modulated carrier signal might be a pair of differential balanced signals. A power amplifier will amplify the modulated carrier signal to a level appropriate for transmission. The one dual-band reconfigurable balun circuit is configured to convert the modulated carrier signal from differential balanced version to an unbalanced version with impedance matching and deliver the modulated carrier signal to the antennas 1012 through filters and the antenna switching circuitry 1010. The multiple antennas 1012 and the replicated transmit and receive circuitries 1006, 1008 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A dual-band reconfigurable balun circuit comprising:
a transformer structure including a primary winding and a secondary winding with a first winding output and a second winding output, wherein:
the primary winding receives a pair of differential signals from an amplifier, and the secondary winding provides an unbalanced single signal at either the first winding output or the second winding output; and
the first winding output is directly connected to an input of a first filter, and the second winding output is directly connected to an input of a second filter;
a first shunt switch coupled between the first winding output and ground; and
a second shunt switch coupled between the second winding output and ground, wherein:
when the amplifier operates in a frequency band of the first filter, the first shunt switch is open and the second shunt switch is closed, such that the unbalanced single signal is transmitted from the first winding output to the first filter, and the second winding output and the second filter are shunted to ground via the closed second shunt switch; and
when the amplifier operates in a frequency band of the second filter, the second shunt switch is open and the first shunt switch is closed, such that the unbalanced single signal is transmitted from the second winding output to the second filter, and the first winding output and the first filter are shunted to ground via the closed first shunt switch.

2. The dual-band reconfigurable balun circuit of claim 1 wherein the transformer structure further includes a first tuning capacitor and a second tuning capacitor, wherein:
the first tuning capacitor is parallel to the first shunt switch and coupled between the first winding output and ground;
the second tuning capacitor is parallel to the second shunt switch and coupled between the second winding output and ground;
when the amplifier operates in the frequency band of the first filter, the first tuning capacitor contributes to an output impedance of the dual-band reconfigurable balun circuit, and the second tuning capacitor is shunted to ground via the closed second shunt switch; and
when the amplifier operates in the frequency band of the second filter, the second tuning capacitor contributes to the output impedance of the dual-band reconfigurable balun circuit, and the first tuning capacitor is shunted to ground via the closed first shunt switch.

3. The dual-band reconfigurable balun circuit of claim 2 wherein the first tuning capacitor and the second tuning capacitor have different capacitances.

4. The dual-band reconfigurable balun circuit of claim 1 wherein:
the first shunt switch has a first parasitic off-state capacitance, and the second shunt switch has a second parasitic off-state capacitance;
when the amplifier operates in the frequency band of the first filter, the first parasitic off-state capacitance of the first shunt switch contributes to an output impedance of the dual-band reconfigurable balun circuit; and
when the amplifier operates in the frequency band of the second filter, the second parasitic off-state capacitance of the second shunt switch contributes to the output impedance of the dual-band reconfigurable balun circuit.

5. The dual-band reconfigurable balun circuit of claim 4 wherein the first parasitic off-state capacitance is different from the second parasitic off-state capacitance.

6. The dual-band reconfigurable balun circuit of claim 1 wherein:
the transformer structure further includes a common tuning capacitor coupled between the first winding output and the second winding output; and
the common tuning capacitor contributes to an output impedance of the dual-band reconfigurable balun circuit regardless of the amplifier operating in the frequency band of the first filter or the frequency band of the second filter.

7. The dual-band reconfigurable balun circuit of claim 1 wherein the transformer structure further includes one or more decoupling capacitors, which are coupled between a midpoint of the primary winding and ground.

8. The dual-band reconfigurable balun circuit of claim 1 further comprising a tuning capacitance structure, wherein:
the tuning capacitance structure is coupled between the first winding output and ground, and/or coupled between the second winding output and ground; and
the tuning capacitance structure is configured to individually tune the output impedance of the dual-band reconfigurable balun circuit for the frequency band of the first filter and the frequency band of the second filter.

9. The dual-band reconfigurable balun circuit of claim 8, wherein:
the tuning capacitance structure includes at least one first additional tuning capacitor, at least one first tuning switch, at least one second additional tuning capacitor, and at least one second tuning switch;
the at least one first additional tuning capacitor and the at least one first tuning switch are coupled in series between the first winding output and ground; and
the at least one second additional tuning capacitor and the at least one second tuning switch are coupled in series between the second winding output and ground.

10. The dual-band reconfigurable balun circuit of claim 9, wherein:
the at least one first additional tuning capacitor comprises a plurality of first additional tuning capacitors and the at least one first tuning switch includes a plurality of first tuning switches, wherein each of the plurality of first additional tuning capacitors and a corresponding one of the plurality of first tuning switches are coupled in series between the first winding output and ground; and
the at least one second additional tuning capacitor comprises a plurality of second additional tuning capacitors and the at least one second tuning switch includes a plurality of second tuning switches, wherein each of the plurality of second additional tuning capacitors and a corresponding one of the plurality of second tuning switches are coupled in series between the second winding output and ground.

11. The dual-band reconfigurable balun circuit of claim 10, wherein:
by selectively closing different numbers of the plurality of first tuning switches, a first combined capacitance between the first winding output and ground is varied in a first range;
by selectively closing different numbers of the plurality of second tuning switches, a second combined capacitance between the second winding output and ground is varied in a second range; and
the first range is different from the second range.

12. The dual-band reconfigurable balun circuit of claim 10, wherein:
by selectively closing different numbers of the plurality of first tuning switches, a first combined capacitance between the first winding output and ground is varied in a first range;
by selectively closing different numbers of the plurality of second tuning switches, a second combined capacitance between the second winding output and ground is varied in a second range; and
the first range is the same as the second range.

13. The dual-band reconfigurable balun circuit of claim 8, wherein:
the tuning capacitance structure includes a plurality of first programmable switches and a plurality of second programmable switches;
each of the plurality of first programmable switches and each of the plurality of second programmable switches has a parasitic off-state capacitance;
the plurality of first programmable switches is coupled in series between the first winding output and ground; and
the plurality of second programmable switches is coupled in series between the second winding output and ground.

14. The dual-band reconfigurable balun circuit of claim 13, wherein:
by selectively turning off different numbers of the first programmable switches, a first combined parasitic capacitance between the first winding output and ground is varied in a first range;
by selectively turning off different numbers of the second programmable switches, a second combined parasitic capacitance between the second winding output and ground is varied in a second range; and
the first range is different from the second range.

15. The dual-band reconfigurable balun circuit of claim 13, wherein:
by selectively turning off different numbers of the first programmable switches, a first combined parasitic capacitance between the first winding output and ground is varied in a first range;
by selectively turning off different numbers of the second programmable switches, a second combined parasitic capacitance between the second winding output and ground is varied in a second range; and
the first range is the same as the second range.

16. A dual-band reconfigurable balun circuit comprising:
a transformer structure including a primary winding and a secondary winding with a first winding output and a second winding output, wherein the primary winding receives a pair of differential signals from an amplifier, and the secondary winding provides an unbalanced single signal at either the first winding output or the second winding output;
a first series switch coupled between the first winding output and an input of a first filter;
a second series switch coupled between the second winding output and an input of a second filter, wherein:
when the amplifier operates in a frequency band of the first filter, the first series switch is closed and the second series switch is open, such that the unbalanced single signal is transmitted from the first winding output to the first filter through the closed first series switch, and the second winding output is isolated from the second filter by the open second series switch; and
when the amplifier operates in a frequency band of the second filter, the second series switch is closed and the first series switch is open, such that the unbalanced single signal is transmitted from the second winding output to the second filter through the closed second series switch, and the first winding output is isolated from the first filter by the open first series switch; and
a tuning capacitance structure coupled between the first winding output and ground, and/or coupled between the second winding output and ground, wherein the tuning capacitance structure is configured to individually tune the output impedance of the dual-band reconfigurable balun circuit for the frequency band of the first filter and the frequency band of the second filter.

17. The dual-band reconfigurable balun circuit of claim 16, wherein:
the tuning capacitance structure includes at least one first additional tuning capacitor, at least one first tuning switch, at least one second additional tuning capacitor, and at least one second tuning switch;
the at least one first additional tuning capacitor and the at least one first tuning switch are coupled in series between the first winding output and ground; and
the at least one second additional tuning capacitor and the at least one second tuning switch are coupled in series between the second winding output and ground.

18. The dual-band reconfigurable balun circuit of claim 17, wherein:
the at least one first additional tuning capacitor comprises a plurality of first additional tuning capacitors and the at least one first tuning switch includes a plurality of first tuning switches, wherein each of the plurality of first additional tuning capacitors and a corresponding one of the plurality of first tuning switches are coupled in series between the first winding output and ground; and
the at least one second additional tuning capacitor comprises a plurality of second additional tuning capacitors and the at least one second tuning switch includes a plurality of second tuning switches, wherein each of the plurality of second additional tuning capacitors and a corresponding one of the plurality of second tuning switches are coupled in series between the second winding output and ground.

19. The dual-band reconfigurable balun circuit of claim 18, wherein:
by selectively closing different numbers of the plurality of first tuning switches, a first combined capacitance between the first winding output and ground is varied in a first range;
by selectively closing different numbers of the plurality of second tuning switches, a second combined capacitance between the second winding output and ground is varied in a second range; and
the first range is different from the second range.

20. The dual-band reconfigurable balun circuit of claim 18, wherein:
by selectively closing different numbers of the plurality of first tuning switches, a first combined capacitance between the first winding output and ground is varied in a first range;
by selectively closing different numbers of the plurality of second tuning switches, a second combined capacitance between the second winding output and ground is varied in a second range; and
the first range is the same as the second range.

21. The dual-band reconfigurable balun circuit of claim 16, wherein:
the tuning capacitance structure includes a plurality of first programmable switches and a plurality of second programmable switches;
each of the plurality of first programmable switches and each of the plurality of second programmable switches provides a parasitic off-state capacitance;
the plurality of first programmable switches is coupled in series between the first winding output and ground; and
the plurality of second programmable switches is coupled in series between the second winding output and ground.

22. The dual-band reconfigurable balun circuit of claim 21, wherein:
by selectively turning off different numbers of the first programmable switches, a first combined parasitic capacitance between the first winding output and ground is varied in a first range;
by selectively turning off different numbers of the second programmable switches, a second combined parasitic capacitance between the second winding output and ground is varied in a second range; and
the first range is different from the second range.

23. The dual-band reconfigurable balun circuit of claim 21, wherein:
by selectively turning off different numbers of the first programmable switches, a first combined parasitic capacitance between the first winding output and ground is varied in a first range;
by selectively turning off different numbers of the second programmable switches, a second combined parasitic capacitance between the second winding output and ground is varied in a second range; and
the first range is the same as the second range.

24. The dual-band reconfigurable balun circuit of claim 16 wherein the transformer structure further includes a first tuning capacitor and a second tuning capacitor, wherein:
the first tuning capacitor is coupled between the first winding output and ground, and the second tuning capacitor is coupled between the second winding output and ground; and
the first tuning capacitor and the second tuning capacitor simultaneously contribute to the output impedance of the dual-band reconfigurable balun circuit regardless of whether the amplifier operates in the frequency band of the first filter or the frequency band of the second filter.

25. The dual-band reconfigurable balun circuit of claim 16 further includes a first shunt switch and a second shunt switch, wherein:
the first shunt switch is coupled between the input of the first filter and ground; and
the second shunt switch is coupled between the input of the second filter and ground, wherein:
when the amplifier operates in the frequency band of the first filter, the first shunt switch is open and the second shunt switch is closed, such that the second filter is shunted to ground via the closed second shunt switch; and
when the amplifier operates in the frequency band of the second filter, the second shunt switch is open and the first shunt switch is closed, such that the first filter is shunted to ground via the closed first shunt switch.

26. A radio frequency (RF) communication module, comprising:
an amplifier;
dual filters including a first filter and a second filter;
antenna switching circuitry (ASW) following the dual filters; and
a dual-band reconfigurable balun circuit coupled between the amplifier and the dual filters, and comprising:
a transformer structure including a primary winding and a secondary winding with a first winding output, wherein the primary winding receives a pair of differential signals from the amplifier, and the secondary winding provides an unbalanced single signal at either of the first winding output and the second winding output;
a first series switch coupled between the first winding output and an input of the first filter;
a second series switch coupled between the second winding output and an input of the second filter, wherein:
when the amplifier operates in a frequency band of the first filter, the first series switch is closed and the second series switch is open, such that the unbalanced single signal is transmitted from the first winding output to the first filter through the closed first series switch, and the second winding output is isolated from the second filter by the open second series switch; and
when the amplifier operates in a frequency band of the second filter, the second series switch is closed and the first series switch is open, such that the unbalanced single signal is transmitted from the second winding output to the second filter through the closed second series switch, and the first winding output is isolated from the first filter by the open first series switch; and
a tuning capacitance structure coupled between the first winding output and ground, and/or coupled between the second winding output and ground, wherein the tuning capacitance structure is configured to individually tune the output impedance of the dual-band reconfigurable balun circuit for the frequency band of the first filter and the frequency band of the second filter.

27. A method, operating in a dual-band reconfigurable balun circuit that is coupled between an amplifier and dual filters and includes a transformer structure and a plurality of switches, comprising:
determining a frequency band in which the amplifier provides a pair of balanced signals to the transformer structure;
determining from which one of two winding outputs of the transformer structure an unbalanced single signal is transmitted to a corresponding one of the dual filters based on the determined frequency band;
programming to turn on/off the plurality of switches, which is between the winding outputs and the dual filters, so as to ensure that the unbalanced single signal is capable of being transmitted to the corresponding one of the dual filters, and an output impedance of the dual-band reconfigurable balun circuit substantially matches an input impedance of the corresponding one of the dual filters; and
converting the pair of balanced signals from the amplifier to the unbalanced single signal and transmitting the unbalanced single signal from the determined one of the winding outputs of the transformer structure to the corresponding one of the dual filters.
